(19) United States
(12) Patent Application Publication
(10) Pub. No.: US 2021/0066162 A1
(43) Pub. Date: Mar. 4, 2021

(54) SEMICONDUCTOR PACKAGE WITH ATTACHMENT AND/OR STOP STRUCTURES

(71) Applicant: Intel Corporation, Santa Clara, CA (US)

(72) Inventors: Sergio A. CHAN ARGUEDAS, Chandler, AZ (US); Nicholas S. HAEHN, Scottsdale, AZ (US); Edvin CETEGEN, Chandler, AZ (US); Nicholas NEAL, Scottsdale, AZ (US); Jacob VEHONSKY, Gilbert, AZ (US); Steve S. CHO, Chandler, AZ (US); Rahul JAIN, Gilbert, AZ (US); Antariksh Rao Pratap SINGH, Gilbert, AZ (US); Tarek A. IBRAHIM, Mesa, AZ (US); Thomas HEATON, Mesa, AZ (US); Vipul MEHTA, Chandler, AZ (US)

(21) Appl. No.: 16/557,896

(22) Filed: Aug. 30, 2019

(51) Int. Cl. H01L 23/42; H01L 23/00

(52) U.S. Cl. CPC H01L 23/42; H01L 24/17

(57) ABSTRACT

A device is disclosed. The device includes a substrate, a die on the substrate, a thermal interface material (TIM) on the die, and solder bumps on a periphery of a top surface of the substrate. An integrated heat spreader (IHS) is formed on the solder bumps. The IHS covers the TIM.

### TECHNICAL FIELD

Embodiments of the disclosure pertain to semiconductor packages with attachment and/or stop structures and, in particular, semiconductor packages with attachment and/or stop structures for integrated heat sinks or stiffeners.

### BACKGROUND

A typical manner of attaching an integrated heat spreader (IHS) or a stiffener frame to a microprocessor package is by forming an adhesive layer around the perimeter of the package for bonding purposes. One of the primary modes of failure of such adhesive bonding is adhesive failure over time. Most polymers used as adhesives create a thin bond between substrate solder resist and a metal (aluminum, nickel, stainless steel, etc.). The thin bond between the polymer and the metal is typically formed by metal oxidation layers. However, the thin bond between the polymer and the metal can weaken with exposure to moisture.

In some approaches, to minimize the problem of bond failure, polymer optimization, elimination of moisture exposure after attachment (wash cycles, cleaning procedures, etc.), and surface treatment for adhesion enhancement (priming, roughening) have been used. However, such approaches minimize but do not eliminate bond failure.

Additionally, if the adhesive layer is too thin it can fail cohesively and can cause the IHS to detach from the package during operation. In general, the adhesive layer is applied without bond line thickness (BLT) control, but the risk of bond failure is high without such a mechanism. Previously bond line thickness control has been provided by embedding large fillers in the matrix of the polymer (adhesive), utilizing a thermal interface material (TIM) layer as a stand-off to define adhesive BLT, and/or adding mechanical BLT control, such as shims or other structures directly onto the IHS.

### BRIEF DESCRIPTION OF THE DRAWINGS

FIG. 1 illustrates a semiconductor package of a previous approach.

FIG. 2A illustrates a semiconductor package that includes attachment structures for integrated heat spreaders or stiffeners according to an embodiment.

FIG. 2B illustrates a top view of an example solder bump pattern that is characterized by solder bumps that are formed around a semiconductor package substrate perimeter according to an embodiment.

FIG. 2C illustrates a top view of an example solder bump pattern that is characterized by solder bumps formed at corners of a semiconductor package substrate perimeter and sealant formed between the solder bumps along side portions of the semiconductor package substrate perimeter according to an embodiment.

FIG. 2D illustrates a top view of an example solder bump pattern that is characterized by sealant that is formed at corners of a semiconductor package substrate perimeter and solder bumps formed between the sealant on side portions of the semiconductor package substrate perimeter according to an embodiment.

FIG. 3 illustrates a semiconductor package that includes an integrated heat spreader stop for thickness control according to an embodiment.

FIGS. 4A and 4B illustrate cross-sections of a package during a process of attaching an integrated heat spreader where shims are not used.

FIGS. 5A and 5B illustrate cross-sections of a package during a process of attaching an integrated heat spreader where shims are used according to an embodiment.

FIG. 6 illustrates a flowchart of a method for forming a semiconductor package with attachment and/or stop structures for an integrated heat spreader or stiffener according to an embodiment.

FIG. 7 illustrates a computer system according to an embodiment.

### DESCRIPTION OF THE EMBODIMENTS

Semiconductor packages with attachment and/or stop structures are described. It should be appreciated that although embodiments are described herein with reference to example semiconductor packages with attachment and/or stop structures, the disclosure is more generally applicable to semiconductor packages with attachment and/or stop structures as well as other type semiconductor packages with attachment and/or stop structures. In the following description, numerous specific details are set forth, such as specific integration and material regimes, in order to provide a thorough understanding of embodiments of the present disclosure. It will be apparent to one skilled in the art that embodiments of the present disclosure may be practiced without these specific details. In other instances, well-known features, such as integrated circuit design layouts, are not described in detail in order to not unnecessarily obscure embodiments of the present disclosure. Furthermore, it is to be appreciated that the various embodiments shown in the Figures are illustrative representations and are not necessarily drawn to scale.

Certain terminology may also be used in the following description for the purpose of reference only, and thus are not intended to be limiting. For example, terms such as “upper”, “lower”, “above”, and “below” refer to directions in the drawings to which reference is made. Terms such as “front”, “back”, “rear”, and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import. As used herein, the phraseology “the perimeter of the substrate” is intended to refer to the perimeter of the top surface of the substrate.

A typical manner of attaching an integrated heat spreader (IHS) or a stiffener frame to a microprocessor is by forming an adhesive layer around the perimeter of the package for bonding purposes. One of the primary modes of failure of such adhesive bonding is adhesive failure over time. Most polymers used as adhesives create a thin bond between substrate solder resist and a metal (aluminum, nickel, stainless steel, etc.). The thin bond between the solder resist and the metal is typically formed by metal oxidation layers. However, the thin bond between the polymer and the metal can weaken with exposure to moisture.

Previously, polymer optimization, elimination of moisture exposure after attachment (wash cycles, cleaning procedures, etc.), and surface treatment for adhesion enhancement (priming, roughening, etc.) have been used to address the problem. However, in general, such approaches minimize the failure, but do not eliminate it.

Additionally, if an adhesive layer is too thin it can fail cohesively and can cause the integrated heat spreader to detach from the package during operation. In general, if thin layered adhesives do not have an external mechanism for bond line thickness control their risk of failure is high. In previous approaches bond line thickness control has been provided by mechanisms that include embedding large fillers in the matrix of the polymer (adhesive), utilizing a thermal interface material layer as a stand-off to define adhesive bond line thickness, or adding mechanical bond line thickness control, such as shims or thickness control features to the IHS.

An approach that addresses the shortcomings of previous approaches is disclosed herein. For example, as part of a disclosed process, solder pillars on the substrate are aligned with the footprint of an integrated heat spreader or stiffener and used to solder them to the substrate. In an embodiment, the soldered bonds do not break with exposure to moisture and can be used as grounding pads to eliminate radio frequency identification (RFID) interference.

In another approach, as part of a disclosed process, solder bumps or “pillars” that are formed on the substrate and that are aligned with the footprint of the integrated heat spreader can act as bond line thickness control elements or shims. In particular, in an embodiment, the solder structures on the substrate eliminate the risk of adhesive failure due to overly thin bonds.

In an embodiment, adhesive bond line thickness control is enabled without additional cost to integrated heat sink manufacturing. In addition, use with any type of thermal interface material (TIM) is enabled. In an embodiment, solder bumps that extend or protrude from the substrate in the integrated heat spreader footprint can be viewed by cross sectional inspection of the integrated heat spreader adhesive, X-ray of the integrated heat sink footprint, lid shear, visual inspection and/or reverse engineering techniques. In an embodiment, a permanent bonding of the integrated heat sink or stiffener to the package is enabled by processes disclosed herein. In addition, in an embodiment, a grounding structure for RFID prevention is provided.

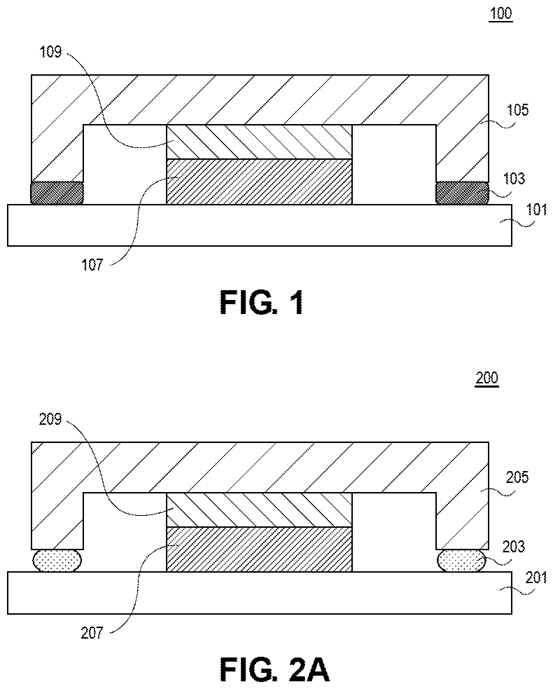

FIG. 1 illustrates a semiconductor package 100 according to a previous approach. In the FIG. 1 embodiment, semiconductor package 100 includes package substrate 101, sealant 103, integrated heat spreader 105, die 107, and thermal interface material 109.

Referring to FIG. 1, semiconductor package 100 features a typical manner of attaching an integrated heat spreader 105 or a stiffener frame to a microprocessor. Namely, by forming an adhesive layer, e.g., sealant 103, around the perimeter of the package for bonding purposes. The thin bond formed between the adhesive and the metal is typically created by metal oxidation layers which can weaken and fail with exposure to moisture.

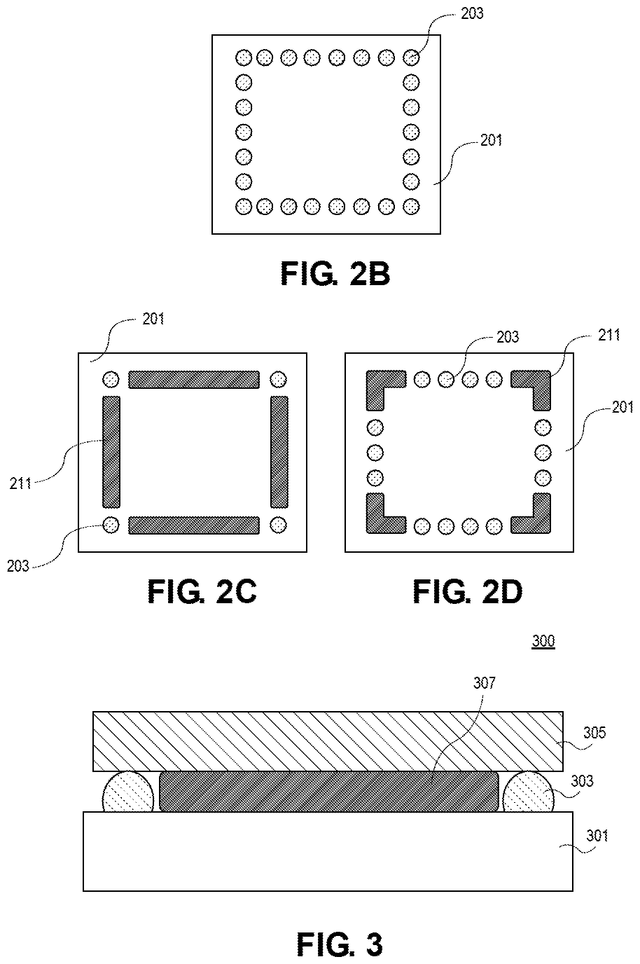

FIG. 2A illustrates a semiconductor package 200 that includes attachment structures according to an embodiment. In the FIG. 2A embodiment, semiconductor package 200 includes package substrate 201, solder bumps 203 (e.g., used as attachment structures), integrated heat spreader 205, die 207, and thermal interface material 209.

Referring to FIG. 2A, in an embodiment, the package substrate 201 can be the base structure upon which the other components of the semiconductor package 200 are formed. In an embodiment, the solder bumps 203 can be formed on the perimeter of the substrate. In an embodiment, the solder bumps 203 can include a bump pattern formed on the perimeter of the package substrate 201. In an embodiment, the solder bumps 203 can be a part of a bump pattern that includes sealant portions. In an embodiment, the solder bumps 203 can be used as attachment structures or “pillars” that extend upward from the package substrate 201 and solders the integrated heat spreader 205 or stiffener to the package substrate 201. In an embodiment, the solder bumps 203 can be formed on the package substrate 201 to be in alignment with the perimeter of the integrated heat spreader 205. In an embodiment, the die 207 can be mounted on the package substrate 201. In an embodiment, the solder bumps 203 can have a thickness in the range of 10-200 um. In other embodiment, the solder bumps 203 can have other thicknesses. In an embodiment, the solder bumps 203 can be separated by a distance of 10 um-10 mm. In other embodiments, the solder bumps 203 can be separated by other distances. In an embodiment, the solder bumps can have a width of 50 um-3 mm. In other embodiments, the solder bumps 203 can have other widths. In an embodiment, the thermal interface material 209 can be formed above the die 207.

In an embodiment, the package substrate 201 can be formed from epoxy, polyimide, Ajinomoto Buildup Film (ABF) film, or synthetic fibers. In other embodiments, the package substrate 201 can be formed form other material. In an embodiment, the solder bumps 203 can be formed from Sn, SnPb, SnPb alloys, nickel, brass, aluminum, tungsten, or zinc. In other embodiments, the solder bumps 203 can be formed from other materials. In an embodiment, the integrated heat spreader 205 can be formed from aluminum, copper, diamond, beryllium, AlSiC or a copper-tungsten alloy. In other embodiments, the integrated heat spreader 205 can be formed from other materials. In an embodiment, the die 207 can be a semiconductor die. In an embodiment, the thermal interface material 209 can be formed from thermal grease, thermal adhesives, thermally conductive pads, or phase change materials. In other embodiments, the thermal interface material 209 can be formed from other materials.

In operation, the failure of the adhesive bond between the integrated heat spreader 205 and the package substrate 201 is prevented by using solder bumps 203 or “pillars” to attach the integrated heat spreader 205 to the package substrate 201. In an embodiment, the solder bumps 203 are aligned with the footprint of the integrated heat spreader 205 or stiffener on the package substrate 201 and are used to solder the integrated heat spreader 205 or stiffener to the package substrate 201. The soldered bonds will not break with exposure to moisture and can be used as grounding pads to eliminate radio frequency identification (RFID) interference.

FIGS. 2B-2D illustrate example solder bump patterns according to an embodiment. FIG. 2B shows a top view of an example solder bump pattern that is characterized by solder bumps 203 that are formed around the perimeter of the package substrate 201. FIG. 2C shows a top view of an example solder bump pattern that is characterized by solder bumps 203 that are formed at corners of the perimeter of the package substrate 201 and sealant 211 formed between the solder bumps 203 along the perimeter of the package substrate 201. FIG. 2D shows a top view of an example solder bump pattern that is characterized by sealant 211 that is formed at the corners of the perimeter of the package substrate 201 and solder bumps 203 that are formed between the sealant 211 along the perimeter of the package substrate 201.

FIG. 3 illustrates a semiconductor package 300 that includes an integrated heat spreader stop for thickness control according to an embodiment. In the FIG. 3 embodiment, the semiconductor package 300 includes substrate 301, solder bumps 303 (used as an integrated heat spreader “stop”), integrated heat spreader 305, and sealant 307.

Referring to FIG. 3, in an embodiment, the substrate 301 can be the base structure upon which other components of the semiconductor package 300 are formed or provided. The solder bumps 303 can be formed on the perimeter of the substrate 301. In an embodiment, the solder bumps 303 can be a part of a bump pattern that extends around the perimeter of the substrate 301. In an embodiment, the solder bumps 303 can be used as mechanical external shims, standoffs or “stops” and thickness control elements to control solder thermal interface material in liquid state. In an embodiment, a shim or standoff is a structure that acts as a spacer, or offset providing mechanism between other structures. In an embodiment, the solder bumps 303 act as a spacer between the substrate 301 and the integrated heat spreader 305. In an embodiment, the solder bumps 303 can be placed on the substrate 301 prior to the attachment of the integrated heat spreader 305. In an embodiment, the solder bumps 303 can have a thickness in the range 10-200 um. In other embodiment, the solder bumps 303 can have other thicknesses. In an embodiment, the solder bumps 303 can have a width of 50 um-10 mm. In other embodiments, the solder bumps 303 can have other widths. In an embodiment, the integrated heat spreader 305 can be bonded to the substrate 301 by the solder bumps 303 and the sealant 307. In an embodiment, the sealant 307 can be formed on the periphery of substrate 301 between solder bumps 303 that are formed adjacent the corners of the substrate 301.

In an embodiment, the substrate 301 can be formed from silicon or germanium. In other embodiments, the substrate can be formed from other material. In an embodiment, the solder bumps 303 can be formed from Sn, SnPb, nickel, brass, aluminum, tungsten, zinc, or tin/lead alloys. In other embodiments, the solder bumps 303 can be formed from other materials. In an embodiment, the integrated heat spreader 305 can be formed from aluminum, copper, diamond, beryllium, AlSiC or a copper-tungsten alloy. In other embodiments, the integrated heat spreader 305 can be formed from other materials. In an embodiment, the sealant 307 can be formed from silicone or epoxy based materials. In other embodiments, the sealant 307 can be formed from other materials.

In operation, cohesive and other type failures of the adhesive layer that cause the detachment of the integrated heat spreader 305 from the semiconductor package 300 are prevented by the bond line thickness control described herein. In an embodiment, the solder bumps 303 are used as mechanical external shims and thickness control elements to control solder thermal interface material in liquid state. In an embodiment, the solder bumps 303 can be placed on the substrate 301 prior to the attachment of the integrated heat spreader 305. In an embodiment, when solder thermal interface material is molten the solder bumps 303 acting as mechanical shims define the thickness of the adhesive (generally referred to as “sealant”). Thus, in an embodiment, the solder bumps 303 can be re-used on the substrate 301 as embedded standoffs or shims for adhesive bond line thickness control. In an embodiment, this technique can be used for integrated heat spreader (e.g., integrated heat spreader 305) or stiffener attachment processes, or to attach any other structure to the substrate 301 using the solder bumps 303.

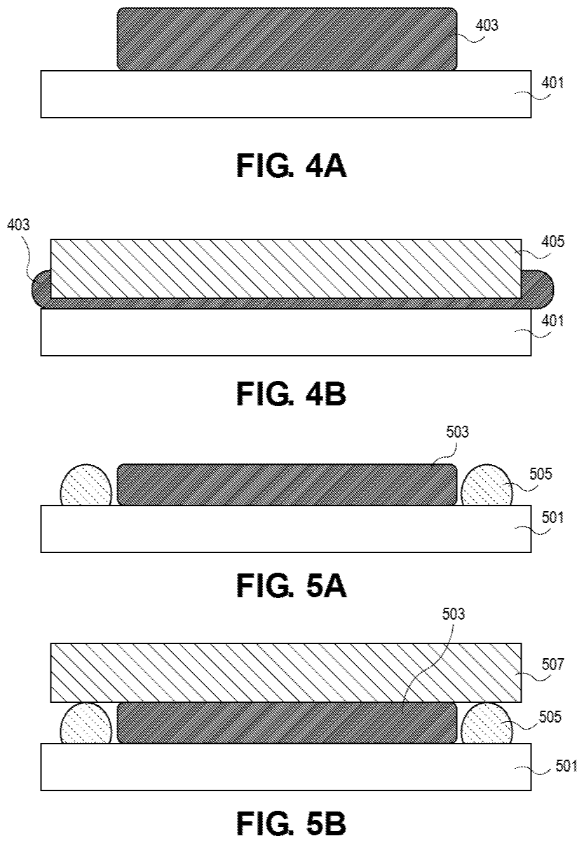

FIGS. 4A and 4B illustrate cross-sections of a package during a process of attaching an integrated heat spreader where shims are not used. FIG. 4A shows substrate 401 and sealant 403. Referring to FIG. 4A, in initial operations the sealant 403 is formed on the substrate 401.

Referring to FIG. 4B, subsequent to one or more operations that result in the cross-section shown in FIG. 4A, integrated heat spreader 405 is formed above the sealant 403. As shown in FIG. 4B, without solder bump shims to provide bond line thickness control the thickness of the sealant 403 between the integrated heat spreader 405 and the substrate 401 can become excessively thin.

FIGS. 5A and 5B illustrate cross-sections of a package during a process of attaching an integrated heat spreader where shims are used. Referring to FIG. 5A, in initial operations, the sealant 503 and the solder bumps 505 are formed on the substrate 501.

Referring to FIG. 5B, subsequent to one or more operations that result in the cross-section shown in FIG. 5A, an integrated heat spreader 507 is formed above the sealant 503 and the solder bumps 505. As shown in FIG. 5B, the solder bumps 505 act as shims that provide bond line thickness control such that the thickness of the sealant 503 between the integrated heat spreader 507 and the substrate 501 is prevented from becoming excessively thin.

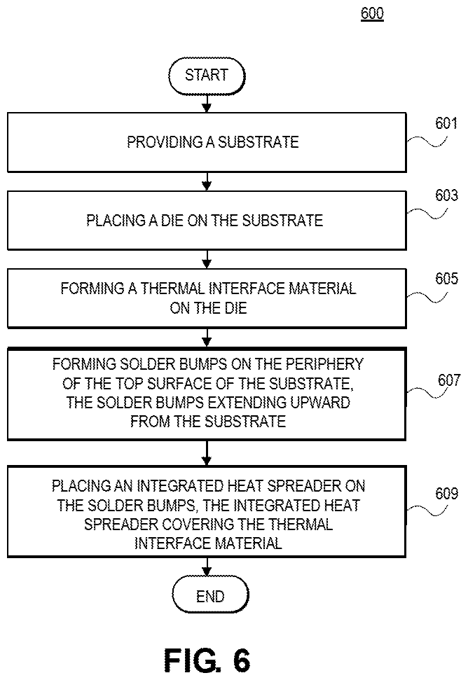

FIG. 6 illustrates a flowchart 600 of a method for forming a semiconductor package with attachment and/or stop structures for an integrated heat spreader or stiffener according to an embodiment. Referring to FIG. 6, the method includes, at 601, providing a substrate. At 603, placing a die on the substrate. At 605, forming a thermal interface material on the die. At 607, forming solder bumps on the periphery of the top surface of the substrate, the solder bumps extending upward from the substrate. At 609, placing an integrated heat spreader on the solder bumps, the integrated heat spreader covering the thermal interface material. In an embodiment, forming the solder bumps includes forming the solder bumps to be in alignment with the periphery of the integrated heat spreader. In an embodiment, forming the solder bumps includes forming the solder bumps to extend upward from the substrate and to have a predetermined thickness. In an embodiment, forming the solder bumps includes forming the solder bumps to be a part of a pattern of attachment material that includes solder bump portions and adhesive portions. In an embodiment, forming the solder bumps includes forming the solder bumps to be a part of a pattern of attachment material that includes solder bump portions at corners of the periphery of the substrate and adhesive portions in other places on the periphery of the substrate. In an embodiment, forming the solder bumps includes forming the solder bumps to be a part of a pattern of attachment material that includes sealant portions at corners of the periphery of the substrate.

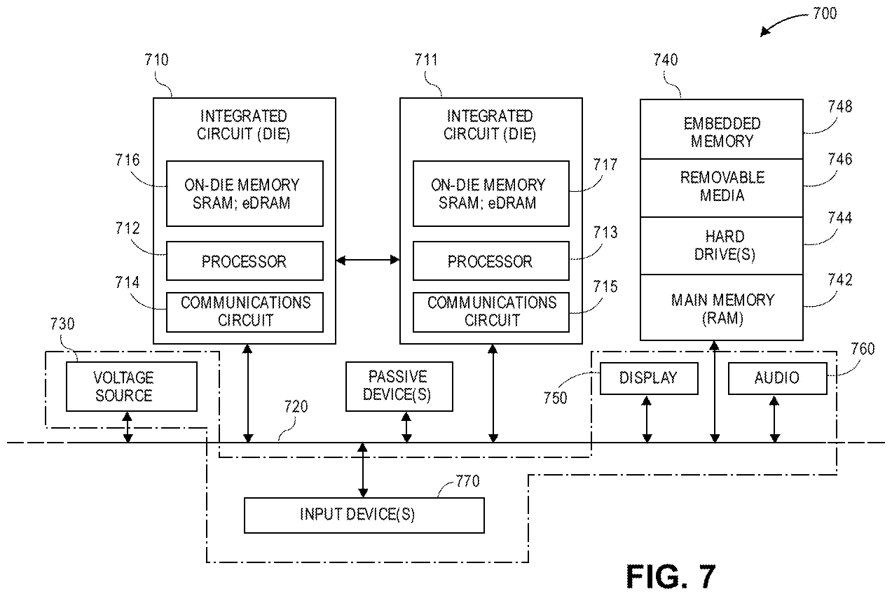

FIG. 7 is a schematic of a computer system 700, in accordance with an embodiment of the present invention. The computer system 700 (also referred to as the electronic system 700) as depicted can embody the semiconductor package 200, according to any of the several disclosed embodiments and their equivalents as set forth in this disclosure. The computer system 700 may be a mobile device such as a netbook computer. The computer system 700 may be a mobile device such as a wireless smart phone. The computer system 700 may be a desktop computer. The computer system 700 may be a hand-held reader. The computer system 700 may be a server system. The computer system 700 may be a supercomputer or high-performance computing system.

In an embodiment, the electronic system 700 is a computer system that includes a system bus 720 to electrically couple the various components of the electronic system 700. The system bus 720 is a single bus or any combination of busses according to various embodiments. The electronic system 700 includes a voltage source 730 that provides power to the integrated circuit 710. In some embodiments, the voltage source 730 supplies current to the integrated circuit 710 through the system bus 720.

The integrated circuit 710 is electrically coupled to the system bus 720 and includes any circuit, or combination of circuits according to an embodiment. In an embodiment, the integrated circuit 710 includes a processor 712 that can be of any type. As used herein, the processor 712 may mean any type of circuit such as, but not limited to, a microprocessor, a microcontroller, a graphics processor, a digital signal processor, or another processor. In an embodiment, the processor 712 includes, or is coupled with, the semiconductor package 200, as disclosed herein. In an embodiment, SRAM embodiments are found in memory caches of the processor. Other types of circuits that can be included in the integrated circuit 710 are a custom circuit or an application-specific integrated circuit (ASIC), such as a communications circuit 714 for use in wireless devices such as cellular telephones, smart phones, pagers, portable computers, two-way radios, and similar electronic systems, or a communications circuit for servers. In an embodiment, the integrated circuit 710 includes on-die memory 716 such as static random-access memory (SRAM). In an embodiment, the integrated circuit 710 includes embedded on-die memory 716 such as embedded dynamic random-access memory (eDRAM).

In an embodiment, the integrated circuit 710 is complemented with a subsequent integrated circuit 711. Useful embodiments include a dual processor 713 and a dual communications circuit 715 and dual on-die memory 717 such as SRAM. In an embodiment, the dual integrated circuit 710 includes embedded on-die memory 717 such as eDRAM.

In an embodiment, the electronic system 700 also includes an external memory 740 that in turn may include one or more memory elements suitable to the particular application, such as a main memory 742 in the form of RAM, one or more hard drives 744, and/or one or more drives that handle removable media 746, such as diskettes, compact disks (CDs), digital variable disks (DVDs), flash memory drives, and other removable media known in the art. The external memory 740 may also be embedded memory 748 such as the first die in a die stack, according to an embodiment.

In an embodiment, the electronic system 700 also includes a display device 750, an audio output 760. In an embodiment, the electronic system 700 includes an input device such as a controller 770 that may be a keyboard, mouse, trackball, game controller, microphone, voice-recognition device, or any other input device that inputs information into the electronic system 700. In an embodiment, an input device 770 is a camera. In an embodiment, an input device 770 is a digital sound recorder. In an embodiment, an input device 770 is a camera and a digital sound recorder.

As shown herein, the integrated circuit 710 can be implemented in a number of different embodiments, including the semiconductor package 200, according to any of the several disclosed embodiments and their equivalents, an electronic system, a computer system, one or more methods of fabricating an integrated circuit, and one or more methods of fabricating an electronic assembly that includes the semiconductor package 200, according to any of the several disclosed embodiments as set forth herein in the various embodiments and their art-recognized equivalents. The elements, materials, geometries, dimensions, and sequence of operations can all be varied to suit particular I/O coupling requirements including array contact count, array contact configuration for a microelectronic die embedded in a processor mounting substrate according to any of the several disclosed semiconductor package embodiments and their equivalents. A foundation substrate may be included, as represented by the dashed line of FIG. 7. Passive devices may also be included, as is also depicted in FIG. 7.

Although specific embodiments have been described above, these embodiments are not intended to limit the scope of the present disclosure, even where only a single embodiment is described with respect to a particular feature. Examples of features provided in the disclosure are intended to be illustrative rather than restrictive unless stated otherwise. The above description is intended to cover such alternatives, modifications, and equivalents as would be apparent to a person skilled in the art having the benefit of the present disclosure.

The scope of the present disclosure includes any feature or combination of features disclosed herein (either explicitly or implicitly), or any generalization thereof, whether or not it mitigates any or all of the problems addressed herein. Accordingly, new claims may be formulated during prosecution of the present application (or an application claiming priority thereto) to any such combination of features. In particular, with reference to the appended claims, features from dependent claims may be combined with those of the independent claims and features from respective independent claims may be combined in any appropriate manner and not merely in the specific combinations enumerated in the appended claims.

The following examples pertain to further embodiments. The various features of the different embodiments may be variously combined with some features included and others excluded to suit a variety of different applications.

Example embodiment 1: A device, comprising: a substrate; a die on the substrate; a thermal interface material (TIM) on the die; solder bumps on a periphery of a top surface of the substrate, the solder bumps extending the upward from the substrate; and an integrated heat spreader (IHS) on the solder bumps, the IHS covering the TIM.

Example embodiment 2: The device of example embodiment 1, wherein the solder bumps are aligned with the periphery of the IHS.

Example embodiment 3: The device of example embodiment 1, or 2, wherein the solder bumps have a thickness in the range 10 to 200 um.

Example embodiment 4: The device of example embodiment 1, 2, or 3, wherein the solder bumps are a part of a pattern of attachment material that includes solder bump portions and adhesive portions.

Example embodiment 5: The device of example embodiment 1, 2, 3, or 4, wherein the solder bumps are a part of a pattern of attachment material that includes solder bump portions at corners of the top surface of the periphery of the substrate and adhesive portions in other places on the top surface of the periphery of the substrate.

Example embodiment 6: The device of example embodiment 1, 2, 3, 4, or 5, wherein the solder bumps are a part of a pattern of attachment material that includes adhesive portions at corners of the periphery of the substrate.

Example embodiment 7: A device, comprising: a substrate; solder bumps on a periphery of a top surface of the substrate, the solder bumps extending the upward from the top surface of the substrate and defining a space; a sealant on the top surface of the substrate, the sealant in the space defined by the solder bumps; and an integrated heat spreader (IHS) on the solder bumps and on the sealant.

Example embodiment 8: The device of example embodiment 7, wherein the solder bumps are aligned with the periphery of the IHS.

Example embodiment 9: The device of example embodiment 7, or 8, wherein the solder bumps have a thickness in the range 10 to 200 um.

Example embodiment 10: The device of example embodiment 7, 8, or 9, wherein the solder bumps and the sealant are a part of a pattern of attachment material that includes solder bump portions and sealant portions.

Example embodiment 11: The device of example embodiment 7, 8, 9, or 10, wherein the solder bumps and the sealant are a part of a pattern of attachment material that includes solder bump portions at corners of the periphery of the top surface of the substrate and sealant portions in other places on the periphery of the top surface of the substrate.

Example embodiment 12: The device of example embodiment 7, 8, 9, 10, or 11, wherein the solder bumps and the sealant are a part of a pattern of attachment material that includes sealant portions at corners of the periphery of the top surface of the substrate.

Example embodiment 13: A system, comprising: one or more processing components; and one or more storage components, at least one of the one or more processing components and the one or more storage components including a device comprising: a substrate; a die on the substrate; a thermal interface material (TIM) on the die; solder bumps on a periphery of a top surface of the substrate, the solder bumps extending upward from the substrate; and an integrated heat spreader (IHS) on the solder bumps, the IHS covering the TIM.

Example embodiment 14: The system of example embodiment 13, wherein the solder bumps are aligned with the periphery of the IHS.

Example embodiment 15: The system of example embodiment 13, or 14, wherein the solder bumps have a thickness in the range 10 to 200 um.

Example embodiment 16: The system of example embodiment 13, 14, or 15, wherein the solder bumps are a part of a pattern of attachment material that includes solder bump portions and adhesive portions.

Example embodiment 17: The system of example embodiment 13, 14, 15, or 16, wherein the solder bumps are a part of a pattern of attachment material that includes solder bump portions at corners of the periphery of the top surface of the substrate and adhesive portions in other places on the periphery of the top surface of the substrate.

Example embodiment 18: The system of example embodiment 13, 14, 15, 16, or 17, wherein the solder bumps are a part of a pattern of attachment material that includes sealant portions at corners of the periphery of the substrate.

Example embodiment 19: A method, comprising: providing a substrate; placing a die on the substrate; forming a TIM on the die; forming solder bumps on a periphery of a top surface of the substrate, the solder bumps extending the upward from the substrate; and placing an integrated heat spreader (IHS) on the solder bumps, the IHS covering the TIM.

Example embodiment 20: The method of example embodiment 19, wherein forming the solder bumps includes forming the solder bumps to be in alignment with the periphery of the IHS.

Example embodiment 21: The method of example embodiment 19, or 20, wherein forming the solder bumps includes forming the solder bumps to have a thickness in the range 10 to 200 um.

Example embodiment 22: The method of example embodiment 19, 20, or 21, wherein forming the solder bumps includes forming the solder bumps to be a part of a pattern of attachment material that includes solder bump portions and adhesive portions.

Example embodiment 23: The method of example embodiment 19, 20, 21, or 22, wherein forming the solder bumps includes forming the solder bumps to be a part of a pattern of attachment material that includes solder bump portions at corners of the periphery of the top surface of the substrate and adhesive portions in other places on the periphery of the top surface of the substrate.

Example embodiment 24: The method of example embodiment 19, 20, 21, 22, or 23, wherein forming the solder bumps includes forming the solder bumps to be a part of a pattern of attachment material that includes adhesive portions at corners of the periphery of the substrate.

Example embodiment 25: A method, comprising: providing a substrate; forming solder bumps on a periphery of a top surface of the substrate, the solder bumps defining a space; forming a sealant on the top surface of the substrate, the forming the sealant on the top surface of the substrate including forming the sealant in the space defined by the solder bumps; and placing an integrated heat spreader (IHS) on the solder bumps and the sealant.

Example embodiment 26: The method of example embodiment 25, wherein forming the solder bumps includes forming the solder in alignment with the periphery of the IHS.

Example embodiment 27: The method of example embodiment 25, or 26, wherein forming the solder bumps includes forming the solder bumps to extend upward from the substrate and to have a thickness in the range 10 to 200 um.

Example embodiment 28: The method of example embodiment 25, 26, or 27, wherein forming the solder bumps includes forming the solder bumps to be a part of a pattern of attachment material that includes solder bump portions and adhesive portions.

Example embodiment 29: The method of example embodiment 25, 26, 27, or 28, wherein forming the solder bumps includes forming the solder bumps to be a part of a pattern of attachment material that includes solder bump portions at corners of the periphery of the top surface of the substrate and adhesive portions in other places on the periphery of the top surface of the substrate.

Example embodiment 30: The method of example embodiment 25, 26, 27, 28, or 29, wherein forming the solder bumps includes forming the solder bumps to be a part of a pattern of attachment material that includes sealant portions at corners of the periphery of the top surface of the substrate.

What is claimed is:

1. A device, comprising:
a substrate;
a die on the substrate;
a thermal interface material (TIM) on the die;
solder bumps on a periphery of a top surface of the substrate, the solder bumps extending upward from the substrate; and
an integrated heat spreader (IHS) on the solder bumps, the IHS covering the TIM.

2. The device of claim 1, wherein the solder bumps are aligned with the periphery of the IHS.

3. The device of claim 1, wherein the solder bumps have a thickness in the range of 10 to 200 um.

4. The device of claim 1, wherein the solder bumps are a part of a pattern of attachment material that includes solder bump portions and adhesive portions.

5. The device of claim 1, wherein the solder bumps are a part of a pattern of attachment material that includes solder bump portions at corners of the periphery of the top surface of the substrate and adhesive portions in other places on the periphery of the top surface of the substrate.

6. The device of claim 1, wherein the solder bumps are a part of a pattern of attachment material that includes adhesive portions at corners of the periphery of the top surface of the substrate.

7. A device, comprising:
a substrate;
solder bumps on a periphery of a top surface of the substrate, the solder bumps extending upward from the substrate and defining a space;
a sealant on the top surface of the substrate, the sealant in the space defined by the solder bumps; and
an integrated heat spreader (IHS) on the solder bumps and the sealant.

8. The device of claim 7, wherein the solder bumps are aligned with the periphery of the IHS.

9. The device of claim 7, wherein the solder bumps have a thickness in the range of 10 to 200 um.

10. The device of claim 7, wherein the solder bumps and the sealant are a part of a pattern of attachment material that includes solder bump portions and sealant portions.

11. The device of claim 7, wherein the solder bumps and the sealant are a part of a pattern of attachment material that includes solder bump portions at corners of the periphery of the top surface of the substrate and sealant portions in other places on the periphery of the top surface of the substrate.

12. The device of claim 7, wherein the solder bumps and the sealant are a part of a pattern of attachment material that includes sealant portions at corners of the periphery of the top surface of the substrate.

13. A system, comprising:
one or more processing components; and
one or more storage components, at least one of the one or more processing components and the one or more storage components including a device comprising:
a substrate;
a die on the substrate;
a thermal interface material (TIM) on the die;
solder bumps on a periphery of a top surface of the substrate, the solder bumps extending upward from the substrate; and
an integrated heat spreader (IHS) on the solder bumps, the IHS covering the TIM.

14. The system of claim 13, wherein the solder bumps are aligned with the periphery of the IHS.

15. The system of claim 13, wherein the solder bumps have a thickness in the range of 10 to 200 um.

16. The system of claim 13, wherein the solder bumps are a part of a pattern of attachment material that includes solder bump portions and adhesive portions.

17. The system of claim 13, wherein the solder bumps are a part of a pattern of attachment material that includes solder bump portions at corners of the periphery of the top surface of the substrate and adhesive portions in other places on the periphery of the top surface of the substrate.

18. The system of claim 13, wherein the solder bumps are a part of a pattern of attachment material that includes adhesive portions at corners of the periphery of the substrate.

19. A method, comprising:
providing a substrate;
placing a die on the substrate;
forming a TIM on the die;
forming solder bumps on a periphery of a top surface of the substrate, the solder bumps extending upward from the substrate; and
placing an integrated heat spreader (IHS) on the solder bumps, the IHS covering the TIM.

20. The method of claim 19, wherein forming the solder bumps includes forming the solder bumps to be in alignment with the periphery of the IHS.

21. The method of claim 19, wherein forming the solder bumps includes forming the solder bumps to have a thickness in the range 10 to 200 um.

22. The method of claim 19, wherein forming the solder bumps includes forming the solder bumps to be a part of a pattern of attachment material that includes solder bump portions and adhesive portions.

23. The method of claim 19, wherein forming the solder bumps includes forming the solder bumps to be a part of a pattern of attachment material that includes solder bump portions at corners of the periphery of the top surface of the substrate and adhesive portions in other places on the periphery of the top surface of the substrate.

24. The method of claim 19, wherein forming the solder bumps includes forming the solder bumps to be a part of a pattern of attachment material that includes adhesive portions at corners of the periphery of the substrate.
